(19) United States
(12) Patent Application Publication
(10) Pub. No.: US 2003/0201915 A1
(43) Pub. Date: Oct. 30, 2003

(54) Computer keyboard

(76) Inventors: Charles S. Anderson JR., Miami, FL (US); Cesar A. Montiel, Miami, FL (US)

Correspondence Address: Richard C. Litman, LITMAN LAW OFFICES, LTD, P.O. Box 15035, Arlington, VA, 22215, US

(21) Appl. No.: 10/128,346

(22) Filed: Apr. 24, 2002

(51) Int. Cl. H03M 11/00; H03K 17/94

(52) U.S. Cl. 341/22; 400/682

(57) ABSTRACT

A computer keyboard includes a first keyboard section and a second keyboard section. The first keyboard section corresponds to a conventional computer keyboard layout. The second keyboard section includes six evenly spaced key category groups. The second keyboard section is adjustably coupled to the first keyboard section by a joint or hinge.

### BACKGROUND OF THE INVENTION

1. Field of the Invention

The present invention relates generally to input devices and in particular to a computer keyboard that provides data input to a computer by alphanumeric or operational keys.

2. Description of Related Art

Computer keyboards are configured for use with personal computers, such as desk-top computers, that generally include a display unit and a main unit which contains all of the essential circuitry of the computer, such as the central processing unit, the power supply and data storage devices (e.g., floppy and hard disk). Personal computers support a variety of applications, some of which require extensive keyboard interaction while others merely require alphanumeric input. Computer users typically choose the type of computer keyboard they want. Conventional computer keyboards are problematic in that they are generally deficient in providing users with the optimization of time, speed, and convenience.

The related art is represented by the following patents of interest.

U.S. Design Pat. No. 359,480, issued on Jun. 20, 1985 to Marilyn M. Levine, shows an ornamental design for a top surface of a set of keys used for English and Japanese symbols based on International Phonetic Association coding in a keyboard configuration. Levine does not suggest a computer keyboard according to the claimed invention.

U.S. Design Pat. No. 420,996, issued on Feb. 22, 2000 to So Siu Leung, shows an ornamental design for a top surface of a left hand function control layout reverse computer keyboard. Leung does not suggest a computer keyboard according to the claimed invention.

U.S. Pat. No. 4,483,634, issued on Nov. 20, 1984 to Werner U. Frey et al., describes a keyboard arrangement where the alphanumeric keyboard is subdivided into two keyfields mounted on a support having a wedge-shaped extension towards an operator which extension is used as an arm rest. Frey et al. does not suggest a computer keyboard according to the claimed invention.

U.S. Pat. No. 4,564,751, issued on Jan. 4, 1986 to Lynn D. Alley et al., describes a wrap-around auxiliary keyboard having a housing, keys positioned in the housing, and circuitry means in the housing. The housing has a base and at least one extension extending from the base that are shaped and positioned with respect to each other so as to be able to wrap-around a primary keyboard. Alley et al. does not suggest a computer

U.S. Pat. No. 4,595,804, issued on Jun. 17, 1986 to Robert N. MacConnell, describes an auxiliary keyboard of generally U-shaped configuration for claimping onto a sstand-alone computer keyboard. MacConnell does not suggest a computer keyboard according to the claimed invention.

U.S. Pat. No. 4,661,005, issued on Apr. 28, 1987 to Roy J. Lahr, describes a keyboard arrangement ro reducing stress and tension experienced by a human operator during communication with an information processing machine. Lahr does not suggest a computer keyboard according to the claimed invention.

U.S. Pat. No. 4,698,618, issued on Oct. 6, 1987 to James G. Liuzzo et al., describes a keyboard that has a numeric array of keys that is surrounded on three sides by separate arrays of specialized function keys. Liuzzo et al. does not suggest a computer keyboard according to the claimed invention.

U.S. Pat. No. 4,964,075, issued on Oct. 16, 1990 to Paul J. Shaver et al., describes an add-on accessory for existing personal computer systems that is a user-definable, keyboard MACRO storage device which operates independently of the hardware and software installed in the computer. Shaver et al. does not suggest a computer keyboard according to the claimed invention.

U.S. Pat. No. 5,001,307, issued on Mar. 19, 1991 to Paul Blaser, describes a keyboard for large scale inexpensive production that has a housing having a front frame and a base part which are connectable with one another by latch elements to support a printed circuit board in a floating manner. Blaser does not suggest a computer keyboard according to the claimed invention.

U.S. Pat. No. 5,387,042, issued on Feb. 7, 1995 to Carl W. Brown, describes a multilingual keyboard system that operates in conjunction with a central processing unit and a logic system having unique software in order to facilitate multilingual typing from a single keyboard. Brown does not suggest a computer keyboard according to the claimed invention.

U.S. Pat. No. 5,408,060, issued on Apr. 18, 1985 to Jari Muurinen, describes an illuminated keyboard in which keys are operable in at least two different modes. German '903 does not suggest a computer keyboard according to the claimed invention.

U.S. Pat. No. 5,650,799, issued on Jul. 22, 1997 to Roger D. Melen, describes a personal imaging computer system connected to a local area network (LAN) that includes a plurality of programmable function keys which can be programmed over the LAN by remote LAN users from their workstations. Melen does not suggest a computer keyboard according to the claimed invention.

U.S. Pat. No. 5,897,257, issued on Apr. 27, 1999 to Rich Chen, describes a keyboard with expandable function keys. Chen does not suggest a computer keyboard according to the claimed invention.

U.S. Pat. No. 5,986,586, issued on Nov. 16, 1999 to Tien-Chin Tsai, describes a keyboard with additional hot keys which kan be used to control and manipulate peripheral equipment. Tsai does not suggest a computer keyboard according to the claimed invention.

U.S. Pat. No. 6,040,822, issued on Mar. 21, 2000 to Mark R. Decker, describes an electronic luminescence keyboard system in a device which includes one or more keypads and an illuminated panel which displays information responsive to the pressing of at least one of the keypads. Decker does not suggest a computer keyboard according to the claimed invention.

U.S. Pat. No. 6,102,594, issued on Aug. 15, 2000 to George Stroøm, describes a keyboard for one-handed touch typing derived from a normal Sholes keyboard, where each charachter-type is assigned two characters, thereby reducing the number of keys to approximately half the number of keys on a normal Sholes keyboard. Stroøm does not suggest a computer keyboard according to the claimed invention.

U.S. Pat. No. 6,111,527, issued on Aug. 29, 2000 to Irving Susel, describes a keyboard assembly that includes two keyboard areas, a primary keyboard which slides apart at the center to reveal an auxiliary keybard area beneath. Susel does not suggest a computer keyboard according to the claimed invention.

U.S. Pat. No. 6,138,050, issued on Oct. 24, 2000 to Gerhard Schneider et al., describes an antenna system for a radio frequency wireless keyboard that includes a metallic plate as a prt of the antenna system. Schneider et al. does not suggest a computer keyboard according to the claimed invention.

U.S. Pat. No. 6,179,496, issued on Jan. 30, 2001 to Chin-Wen Chou, describes a keyboard structure that includes a base, a pan body, and a top cover. Schneider et al. does not suggest a computer keyboard according to the claimed invention.

Japan Patent document 10-222278, published on Aug. 21, 1998, describes an auuxiliary device for keyboard input that is connected between a main body of a personal computer and a keyboard. Japan '278 does not suggest a computer keyboard according to the claimed invention.

Great Britain Patent document 2 352 545 A, published on Jul. 26, 2000, describes a data transmission method of a wireless keyboard. Great Britain '545 does not suggest a computer keyboard according to the claimed invention.

None of the above inventions and patents, taken either singly or in combination, is seen to describe the instant invention as claimed.

### SUMMARY OF THE INVENTION

In one preferred embodiment, a computer keyboard includes a first keyboard section and a second keyboard section. The first keyboard section corresponds to a conventional computer keyboard layout. The second keyboard section includes six evenly spaced key category groups. The second keyboard section is adjustably coupled to the first keyboard section by a joint or hinge. The joint or hinge has a tube or cylindrical surface and a curved channel in the first keyboard section. The cylindrical surface and the channel extend longitudinally approximately parallel to a rear edge of the first keyboard section along a rotational axis. The channel has a circular cross-section configured to receive the cylindrical surface so that the second keyboard section can pivotally adjust with respect to the first keyboard section about the rotational axis over a predetermined adjustment range, preferably between about 0° and 90°, and can remain at a desired position by use of a locking mechanism.

The first computer keyboard section corresponds to a conventional computer keyboard layout. The first computer keyboard includes alphanumeric keys, function keys, cursor control keys, and numeric keys. The second computer section includes six evenly spaced key category groups.

The first key group includes a matrix of four rows by seven columns. The first key group preferably includes programmable keys that enable a user to selectively program user preferred words, text, or the like, such as words or text related to the Internet, college studies, business, or the like.

The second key group includes a matrix of four rows by three columns. The second key group preferably includes predefined keys that enable a user to type common associated words by the touch of one key stroke. The common associated words shown for the second key group may include pronouns.

The third key group preferably includes a matrix of four rows by two columns. The third key group preferably includes predefined function keys that enable a user to type common associated words by the touch of one key stroke. The common associated keys for the third key group may be interrogatives.

The fourth key group preferably includes a matrix of four rows by three columns. The fourth key group preferably includes predefined function keys that enable a user to type common associated words by the touch of one key stroke. The common associated keys for the fourth key group may be days of the week.

The fifth key group preferably includes a matrix of four rows by three columns. The fifth key group preferably includes predefined function keys that enable a user to type common associated words by the touch of one key stroke. The common associated keys shown for fifth key group may be months of the year.

The sixth key group preferably includes a matrix of four rows by two columns. The sixth key group preferably includes function keys that enable a user to type a predetermined function by the touch of one key stroke. The common associated keys shown for the sixth key group may include functions.

The computer keyboard includes light-emitting devices mounted under each key of the keyboard, which emit light by using light-emitting diodes (LEDs), so the user may easily distinguish the symbols on the keys in a dark place or in darkness. The light-emitting devices do not occupy much space inside the keys. When a “LIGHT ON OFF” key in the second computer section is depressed by a user to turn the lights on, all of the LEDs are provided with power so that they emit light. When the “LIGHT ON OFF” switch is depressed by a user to turn the lights off, all power to the LEDs is cut off.

One aspect of the present invention is to provide a computer keyboard that can overcome the problems of the prior art.

It is another aspect of the invention to provide improved elements and arrangements of a computer keyboard for the purposes described which is inexpensive, dependable, and fully effective in accomplishing its intended purposes.

These and other aspects and advantages of the present invention will become readily apparent upon further review of the following specification and drawings.

### BRIEF DESCRIPTION OF THE DRAWINGS

FIG. 1 is a front perspective view of a computer keyboard according to the present invention.

FIG. 2 is a top view of the computer keyboard shown in FIG. 1.

FIG. 3 is a top view the first key group of the computer keyboard shown in FIG. 1.

FIG. 4 is a top view of the second key group of the computer keyboard shown in FIG. 1.

FIG. 5 is a top view of the third key group of the computer keyboard shown in FIG. 1.

FIG. 6 is a top view of the fourth key group of the computer keyboard shown in FIG. 1.

FIG. 7 is a top view of the fifth key group of the computer keyboard shown in FIG. 1.

FIG. 8 is a top view of the sixth key group of the computer keyboard shown in FIG. 1.

Similar reference characters denote corresponding features consistently throughout the attached drawings.

### DETAILED DESCRIPTION OF THE PREFERRED EMBODIMENTS

This invention relates to a computer keyboard. The invention disclosed herein is, of course, susceptible of embodiment in many different forms. Shown in the drawings and described hereinbelow in detail are preferred embodiments of the invention. It is to be understood, however, that the present disclosure is an exemplification of the principles of the invention and does not limit the invention to the illustrated embodiments.

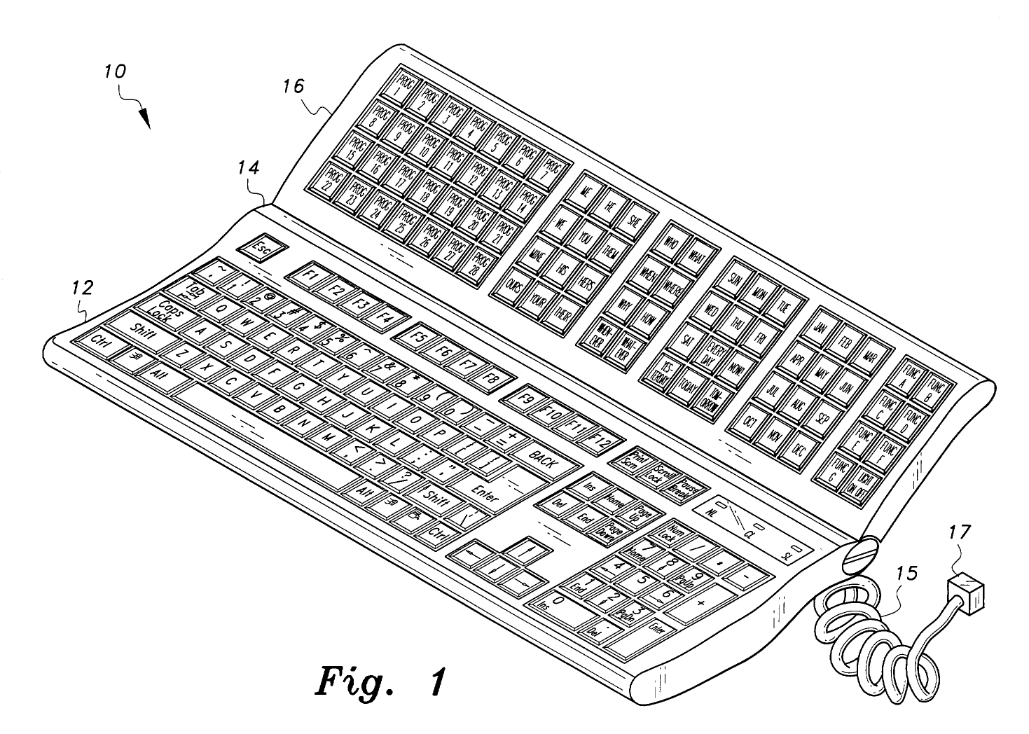

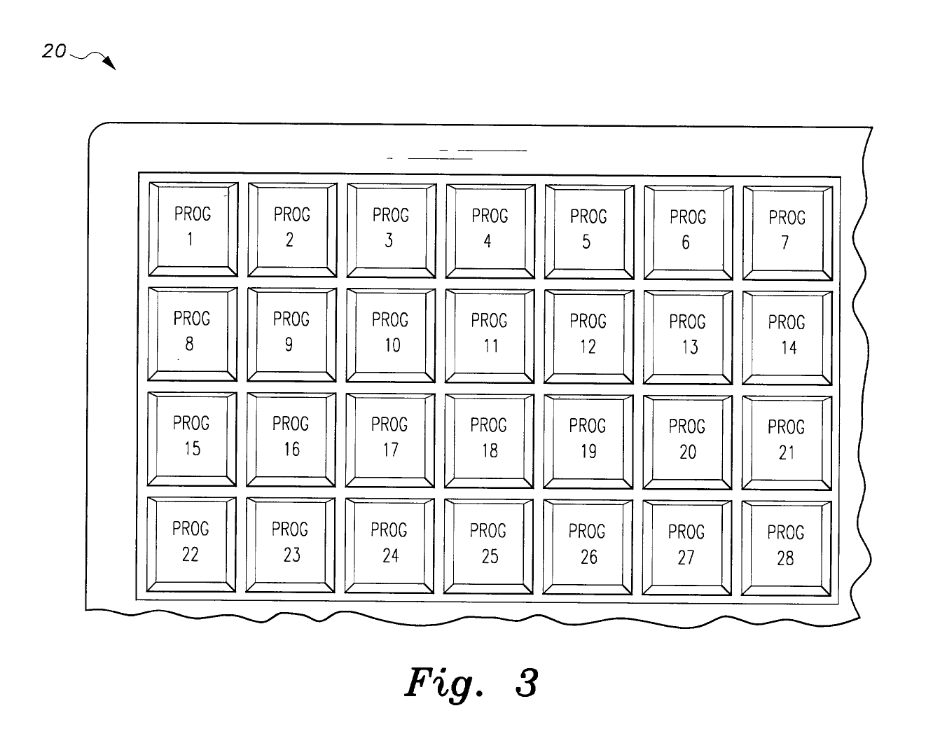

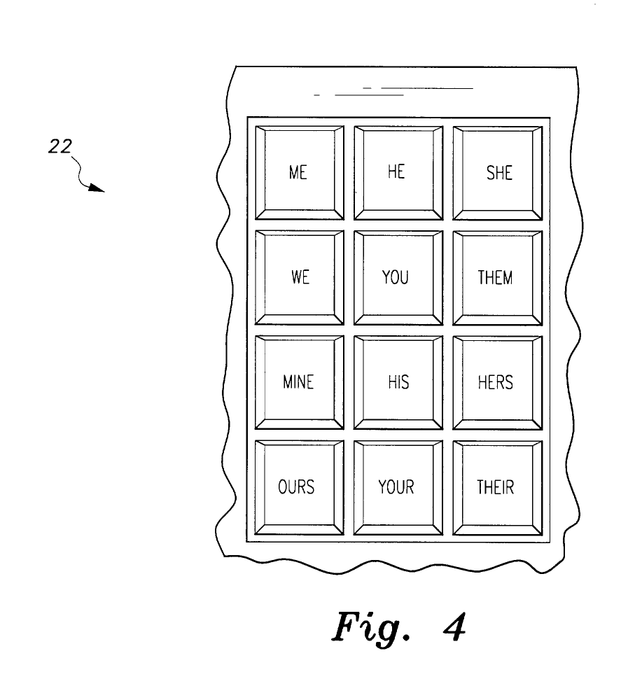

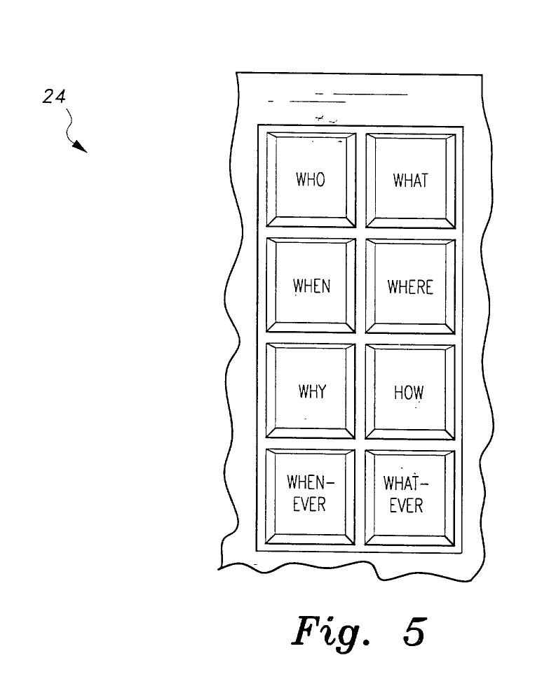

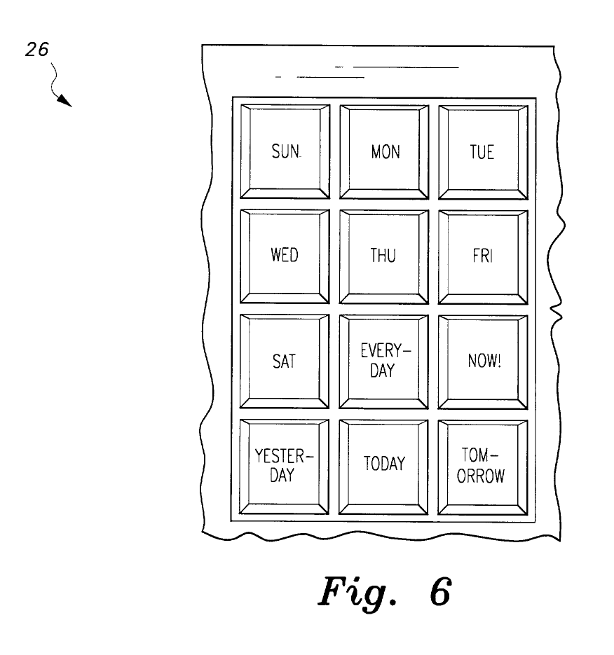

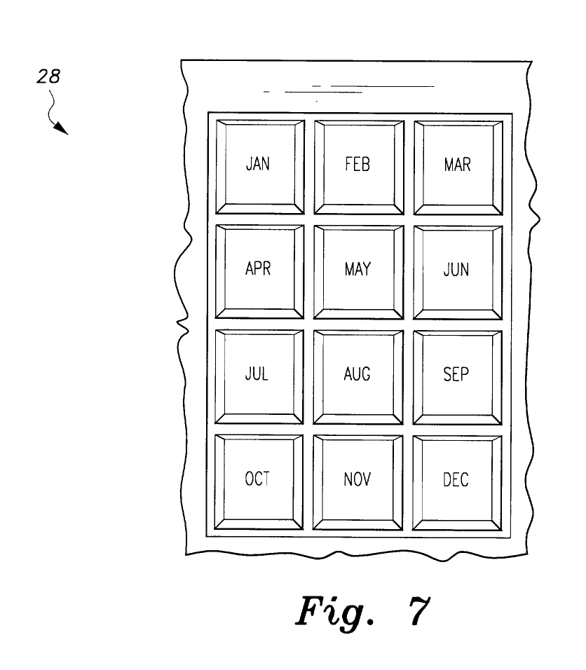

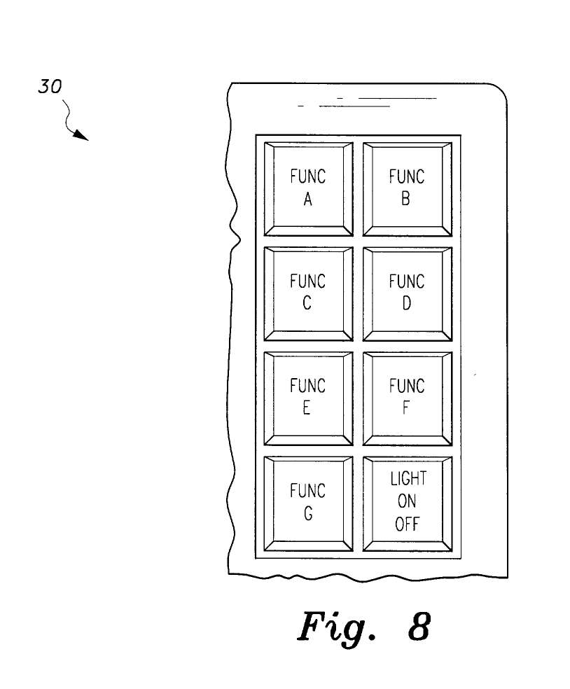

Referring to FIGS. 1-8, computer keyboard 10 is illustrated as detached or decoupled from a computer (not shown). Computer keyboard 10 serves as an exemplary embodiment of a keyboard layout and is not to be taken as a limitation. Alternative keyboard layouts for providing other sets of functions should be apparent to those skilled in the art.

Computer keyboard 10 includes a first keyboard section 12 and a second keyboard section 16. First keyboard section 12 corresponds to a conventional computer keyboard layout. Second keyboard section 14 includes six key groups 20, 22, 24, 26, 28, and 30 that will be described in more detail below. Second keyboard section 16 is adjustably coupled to first keyboard section 12 by a joint or hinge 14. The joint or hinge 14 has a tube or cylindrical surface and a curved channel in the first keyboard section 12. The cylindrical surface and the channel extend longitudinally approximately parallel to a rear edge of the first keyboard section 12 along a rotational axis. The channel has a circular cross-section configured to receive the cylindrical surface so that the second keyboard section 12 can pivotally adjust with respect to the first keyboard section 12 about the rotational axis over a predetermined adjustment range, preferably between about 0° and 90°, and can remain at a desired position. Instead of this particular joint, other joints may be used that allow the second keyboard section 14 to pivotally adjust with respect to the first keyboard section 12 about the rotational axis.

Computer keyboard 10 is intended for use with a conventional personal computer (not shown). A conventional personal computer is coupled to a monitor and includes includes a microprocessor, random access memory, read only memory, and one or more storage devcies, such as a hard disk drive, a floppy disk drive (into which a floppy disk can be inserted), an optical disk drive, and a digital tape cartridge drive. Computer keyboard 10 is not limited to any type of computer. The construction and operation of such computers are well known in the art. A monitor (not shown) permits the display of information for viewing by a user of the computer. This invention is likewise not limited to any particular monitor. Monitors include cathode ray tube displays, as well as flat panel displays such as liquid crystal displays.

Computer keyboard 10 is shown as having a wired interface 15 for coupling to a computer via a plug 17. When computer keyboard 10 is coupled to a computer, the computer keyboard communicates with the computer by a keyboard controller and supporting circuitry located within the computer to receive the information generated by the computer keyboard. Implementation of a wired interface is well known to those skilled in the art. Computer keyboard 10 may alternatively be coupled to a computer by a wirelesss interface (not shown). Such wireless interfaces may be implemented in either the infrared or radio frequency spectrum. Implementation of a wireless interface via any one of these frequency spectrums is well known to those skilled in the art.

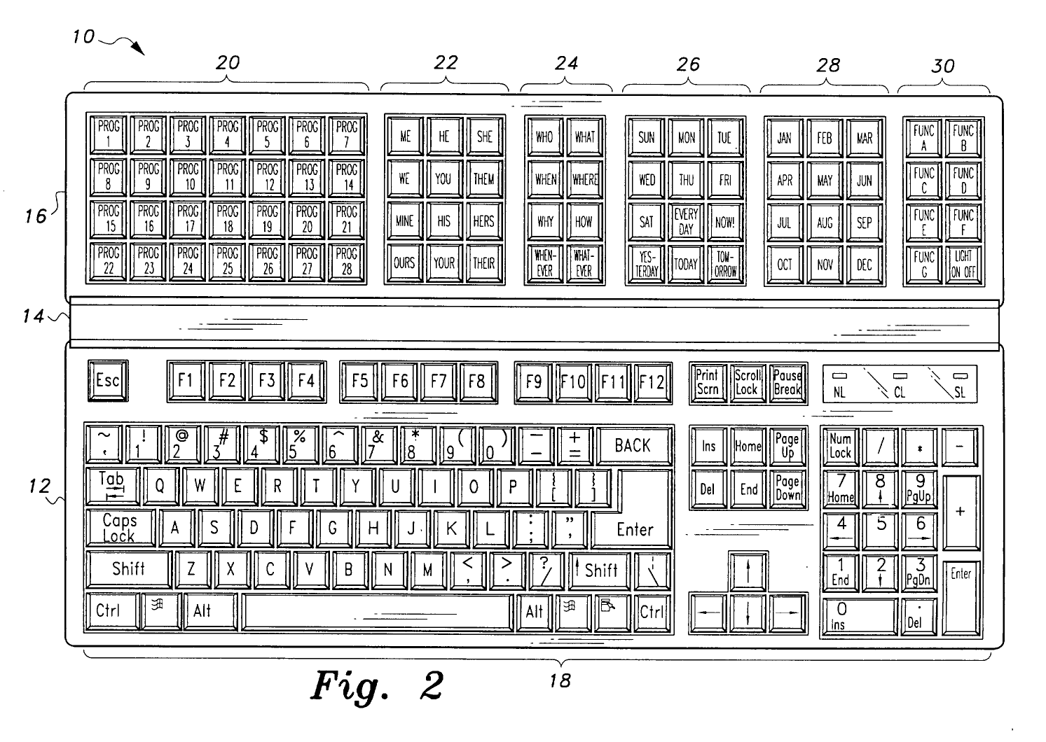

Computer keyboard 10 is designed to provide a comfortable feel to a user. For example, computer keyboard 10 is designed so that its center line and center of gravity are ideally located to provide a balanced feel. Computer keyboard 10 includes numeric keys, letter keys, function keys, programmable keys, and symbolic keys. As shown in FIGS. 1 and 2, first computer section 12 represents a conventional computer keyboard and includes a plurality of key groups that include alphanumeric keys, function keys, cursor control keys, and numeric keys. Second computer section 16 includes six evenly spaced key groups 20, 22, 24, 26, 28, and 30.

Key group 20 is shown to include a matrix of four rows by seven columns. Key group 20 preferably includes programmable keys that enable a user to selectively program user preferred words, text, or the like, such as words or text related to the Internet, college studies, business, or the like. The predetermined program keys shown for key group 20 are numerically identified programs that include “PROG 1”, “PROG 2”, “PROG 3”, . . . , and “PROG 28”.

Key group 20 is shown to include a matrix of four rows by three columns.

Key group 22 is shown to include a matrix of four rows by three columns. Key group 22 preferably includes predefined keys that enable a user to type common associated words by the touch of one key stroke. The common associated words shown for key group 22 are pronouns that include “ME”, “HE”, “SHE”, “WE”, “YOU”, “THEM”, “MINE”, “HIS”, “HERS”, “OURS”, YOUR”, and “THEIR”.

Key group 24 is shown to include a matrix of four rows by two columns. Key group 24 preferably includes predefined function keys that enable a user to type common associated words by the touch of one key stroke. The common associated keys shown for key group 24 are interrogatives that include “WHO”, “WHAT”, “WHEN”, “WHERE”, “WHY”, “HOW”, “WHEN EVER”, and “WHAT EVER”.

Key group 26 is shown to include a matrix of four rows by three columns. Key array 26 preferably includes predefined function keys that enable a user to type common associated words by the touch of one key stroke. The common associated keys shown for key group 26 are days of the week that include “SUN”, “MON”, “TUE”, “WED”, “THU”, “FRI”, “SAT”, “EVERY DAY”, “NOW!”, “YESTERDAY”, TODAY”, and “TOMORROW”.

Key group 28 is shown to include a matrix of four rows by three columns. Key group 28 preferably includes predefined function keys that enable a user to type common associated words by the touch of one key stroke. The common associated keys shown for key group 28 are months of the year that include “JAN”, “FEB”, “MAR”, “APR”, “MAY”, “JUN”, “JUL”, “AUG”, “SEP”, “OCT”, “NOV”, and “DEC”.

Key group 30 is shown to include a matrix of four rows by two columns. Key group 30 preferably includes function keys that enable a user to type a predetermined function by the touch of one key stroke. The common associated keys shown for key group 30 are functions that include “FUNC 1”, “FUNC 2”, “FUNC 3”, “FUNC 4”, “FUNC 5”, “FUNC 6”, “FUNC 7”, and “FUNC 8”.

Individuals generally want to use time effectively in order to reach the highest working efficiency. Computer keyboard 10 includes light-emitting devices mounted under each key of the keyboard, which emits light by using light-emitting diodes (LEDs), so the user may easily distinguish the symbols on the keys in a dark place or in darkness. The light-emitting devices do not occupy much space inside the keys. When the “LIGHT ON OFF” key in second computer section 16 is depressed by a user to turn the lights on, all of the LEDs are provided with power so that they emit light. When the “LIGHT ON OFF” switch is depressed by a user to turn the lights off, all power to the LEDs is cut off.

As shown in FIGS. 1-8, each key has a typical alphanumeric or operational notation on its top or tactile surface. Alternatively, the keys may be blank, and the user may utilize preprinted keycaps or keyboard overlays (templates) for specific key configurations. The keys are generally arranged to approximate the spacing of adult fingers, with close gaps between the keys sufficient to allow clearance without substantial interference.

Each key may be coded by color, shape or other graphic symbol, and may also be coded by texture. The keys are preferably of the type requiring mechanical movement for activation. Mechanically actuated keys preferably have a depression stroke of at least one millimeter, and preferably two to five millimeters. In addition, the keys preferably have tactile feedback, as known in the art. Audible feedback may also be provided, either through a mechanical feedback mechanism associated with the keyboard or key structure, a separate electronic mechanism in computer keyboard 10, or through software in the personal computer to which computer keyboard 10 is attached.

It is possible to include a touch sensitive surface to computer keyboard 10. However, it is preferred that the input keys be provided having a travel in excess of one millimeter be provided to provide a keyboard feel. A touch sensitive surface may be superimposed on a display surface, or a separate area. If a touch sensitive surface is provided, this surface is preferably provided for acquiring dynamic input. The touch sensitive surface may interface through a keyboard port.

Computer keyboard 10 preferably has a membrane layer which prevents dirt, food, liquids, and the like from entering the electrical workings of computer keyboard 10. The membrane layer, which may be a replaceable polymer overlay, provides an opportunity for customization, allowing the shape, color and labeling of the keys to be modified.

The electrical switches actuated by computer keyboard 10 according to the present invention operate in a known manner. In particular, a conventional computer keyboard generally has a capacitance sensing key array. Other types of known manual input devices, adaptable for use with computer keyboard 10 include rubber dome, membrane with mechanical keys, force sensing resistors, optical sensors, touch sensitive array (acoustic wave, resistive, capacitive, etc.) and the like.

Computer keyboard 10 may also include a joystick, trackball, force sensing resistor-based pointing device, or other known directional input devices. These devices may have outputs which are mapped to keycodes and transmitted through a keyboard port to the computer, or are transmitted to the computer through a different port, such as a serial, parallel, SCSI, joystick, or other port type.

It is to be understood that the present invention is not limited to the preferred embodiments, which are illustrative. Various modifications will occur to those of ordinary skill in the art which are within the scope of the present invention.

I claim:

1. A computer keyboard comprising:
a first keyboard section;
a second keyboard section including six evenly spaced key category groups; and
a hinge configured to pivotably adjustably connect the second computer keyboard section with the first computer keyboard section.

2. The computer keyboard according to claim 1, wherein said key category groups include a first key group, a second key group, a third key group, a fourth key group, a fifth key group, and a sixth key group.

3. The computer keyboard according to claim 2, wherein said first key group includes a matrix of four rows by seven columns.

4. The computer keyboard according to claim 2, wherein said second key group includes a matrix of four rows by three columns.

5. The computer keyboard according to claim 2, wherein said third key group includes a matrix of four rows by two columns.

6. The computer keyboard according to claim 2, wherein said fourth key group includes a matrix of four rows by three columns.

7. The computer keyboard according to claim 2, wherein said fifth key group includes a matrix of four rows by three columns.

8. The computer keyboard according to claim 2, wherein said sixth key group includes a matrix of four rows by two columns.

9. The computer keyboard according to claim 1, wherein said first key section and said second key section include light-emitting devices mounted under each key of the keyboard.

10. The computer keyboard according to claim 9, wherein said light-emitting devices emit light by using light-emitting diodes.

11. The computer keyboard according to claim 9, wherein said second keyboard section includes a “LIGHT ON OFF” key to activate and deactivate the light-emitting devices.
